(19) United States
(12) Patent Application Publication
(10) Pub. No.: US 2019/0307018 A1
(43) Pub. Date: Oct. 3, 2019

(54) HIGH DENSITY INTERLOCKING FINS FOR HEATSINK OR COLD PLATE

(71) Applicant: International Business Machines Corporation, Armonk, NY (US)

(72) Inventors: Christopher M. MARROQUIN, Rochester, MN (US); Scott A. SHURSON, Mantorville, MN (US); Eric A. ECKBERG, Rochester, MN (US); Prabjit SINGH, Poughkeepsie, NY (US)

(21) Appl. No.: 15/937,480

(22) Filed: Mar. 27, 2018

(51) Int. Cl. H05K 7/20; F28F 3/02

(52) U.S. Cl. CPC H05K 7/20254; F28F 3/02; H05K 7/20009

(57) ABSTRACT

A method and apparatus includes a first fin structure having a flat portion for a cooling medium to travel across. The first fin structure additionally includes a coupling portion on a first edge of the flat portion. The coupling portion may include an aperture and an arm. The coupling portion may be long enough to attach to a corresponding aperture in a corresponding coupling portion of a corresponding second sink fin structure. The corresponding second sink fin structure may be more than one fin structure away from the first heat sink fin.

This invention was made with Government support under contract number 4000132513&B604143 awarded by the Department of Energy. The Government has certain rights in this invention.

### BACKGROUND

The present invention relates to temperature management in electrical systems, and more particularly, to heat sink and cold plate technologies.

In cooling applications, aluminum or copper sheets are commonly used as fins to create surface area to remove heat from an object. In many applications, these sheets are formed into C-shaped profiles having top and bottom legs. The legs are used to create and maintain a spacing, or pitch, between fins. While effective at removing heat, the space considerations of the C-shaped structures can limit their effective uses.

### SUMMARY

According to one embodiment of the present invention, an apparatus includes a first fin structure having a flat portion for a cooling medium to travel across. The first fin structure additionally includes a coupling portion on a first edge of the flat portion. The coupling portion may include an aperture and an arm. The coupling portion may be long enough to attach to a corresponding aperture in a corresponding coupling portion of a corresponding second sink fin structure. The corresponding second sink fin structure may be more than one fin structure away from the first heat sink fin.

According to another particular embodiment, an apparatus includes a first fin structure for a cooling medium to travel across, where the first fin structure includes a coupling portion. A second fin structure may be configured to be attached to the first fin structure via the coupling portion, and a third fin structure may be positioned between the first and second fin structures, where the coupling structure extends through the third fin structure.

According to another aspect, a method of manufacturing a plurality of fin structures includes positioning a first fin structure within the plurality of fin structures, where a flat portion of the first fin structure allows a cooling medium to travel across. The method further includes creating a coupling portion on a first edge of the flat portion, the coupling portion having an aperture, and also having an arm. The coupling portion is attached to a corresponding aperture in a corresponding coupling portion of a corresponding second sink fin structure. The corresponding second sink fin structure may be more than one sink fin structure away from the first heat sink fin.

### BRIEF DESCRIPTION OF THE SEVERAL VIEWS OF THE DRAWING

FIG. 1 shows a perspective view an apparatus that includes a first fin structure consistent with an embodiment and having a flat portion for a cooling medium to travel across;

FIG. 2 illustrates a perspective view of an assembled plurality of fins consistent with an embodiment;

FIG. 3 is a side view of an assembled plurality of fins consistent with an embodiment;

FIG. 4 is a magnified perspective of the assembled plurality of fins of FIG. 3, and

FIG. 5 is a flowchart showing an embodiment of a method consistent with an embodiment.

### DETAILED DESCRIPTION

An embodiment of a heat sink or cold plate system may achieve tight fin spacing by interlocking legs of adjacent rows of fin sheets. This interlocking may overcome conventional fin bending fabrication limitations. Rather than each fin having a formed leg that contacts a next fin, the system may have fins interlocked between adjacent fins with cutouts on the adjacent fin. The cutouts may allow the leg of the first fin to extend to two times the fin pitch. This configuration may allow the fins to be placed on a tighter spacing than would be allowed by metal forming processes.

An example of the system creates cutouts that allow interlocking extensions to span every other fin structure to tighten up fin pitch. The system changes the formed leg portion of the fin to create openings that align with legs of adjacent fins. This may allow the fin legs to meet minimum fabrication requirements. The leg may pass over openings in the adjacent fin, which allows the legs not to dictate the fin pitch. The resultant interlocking fins enable a tighter pitch, which may allow for more effective heat transfer with less expensive forming processes.

An embodiment of the system may result is less direct surface area between a heat generating object and a vertical portion of the fin from which the air or water is removing heat. The cutouts in the leg may result in the heat being laterally spread to an active portion of the fin. To address this, more legs may be introduced that are narrower in width. This configuration creates a condition where there is less lateral spreading needed for the heat to transfer from the legs to the vertical area of the fin, as well as to the cooling medium.

The fins are configured to have a relatively tighter pitch. The tighter pitch may allow for more effective heat transfer under certain conditions. A formed leg portion of the fin may include openings that align with legs of adjacent fins. This feature may allow the fin legs to meet minimum fabrication requirements.

Each fin of the system may lock into a fin that is a position away. Put another way, each fin may only be locked with every other (e.g., skipping an adjacent) fin. As such, there may be two or more groups of fins. A first group of fins may be all locked together. The second group of fins may be similarly all locked together. Put another way, since each fin locks into a fin two positions away, the fin sections are only locked with every other fin section.

To maintain consistent fin section spacing, an emboss or other spacing mechanism may lock a first group of fin sections to a second group of fin sections. Features such as embosses at the periphery of a fin pack may be used to prevent relative motion between the fin structure groups without hindering air or water flow significantly.

An embodiment of the system may include a continuous length with cutouts. The system may include at least two, complementing, or matching configurations so that horizontal sections interlock with each other. In this manner, the pitch is not limited by a length of the horizontal sections. A component, or fin section, may span one or more adjacent fin sections before connecting to a paired fin section. For instance, while fin sections in the figure skip one fin section before interlocking with a paired fin section, fin sections of another embodiment may span three, four, or more fin sections before interlocking with a matched fin section. While complementary fin sections may have identical structures, matching fin sections of another embodiment may have different configurations. Water or air may be directed through the fins (e.g., in a heat sink or cold plate application) to pull away heat.

Extension portions, or arms, of a first fin component are angled down and fit through a cutout portion of a second fin component. The complementary parts interleave, and the interlocking of the paired parts allows for a small pitch. A pitch includes a dimension from the start of one fin to the start of another fin from an end on view perspective.

Each fin of the system may lock into a fin that is a position away. Put another way, each fin may only be locked with every other (e.g., skipping an adjacent) fin. As such, there may be two or more groups of fins. A first group of fins may be all locked together. The second group of fins may be similarly all locked together. Put another way, since each fin locks into a fin two positions away, the fin sections are only locked with every other fin section.

To maintain consistent fin section spacing, an emboss or other spacing mechanism may lock a first group of fin sections to a second group of fin sections. Features such as embosses at the periphery of a fin pack may be used to prevent relative motion between the fin structure groups without hindering air or water flow significantly.

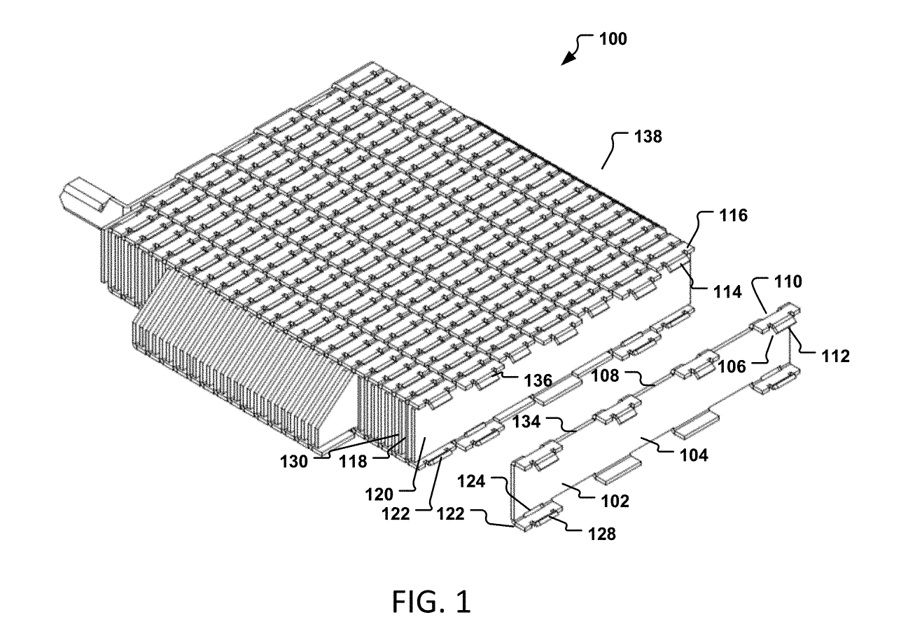

Turning more particularly to the Drawings, FIG. 1 shows a perspective view an apparatus 100 that includes a first fin structure 102 having a flat portion 104 for a cooling medium to travel across. The first fin structure 102 additionally includes a coupling portion 106 on a first edge 108 of the flat portion 104. The coupling portion 106 may include an aperture 110 and an arm 112. The coupling portion 106 may be long enough to attach to a corresponding aperture in a corresponding coupling portion of a corresponding second sink fin structure (not shown). The corresponding second sink fin structure may be more than one fin structure away from the first heat sink fin. As shown in FIG. 1, an arm 114 of a coupling portion 116 of a fin structure 118 may be configured to fit through the aperture 110. A fin structure 120 is in between the fin structure 102 and the fin structure 118. A fin structure 130 may be the corresponding fin structure to attach to fin structure 120.

An arm 122 of the fin structure 118 of the plurality of fins 138 may be configured to fit through an aperture 124 of a coupling portion 126 of the fin structure 102. The coupling portion 126 of the fin structure 102 also includes an arm 128. The fin structure 102 may include a space, or cutout 134, to pass through a coupling portion 136 of the fin structure 120.

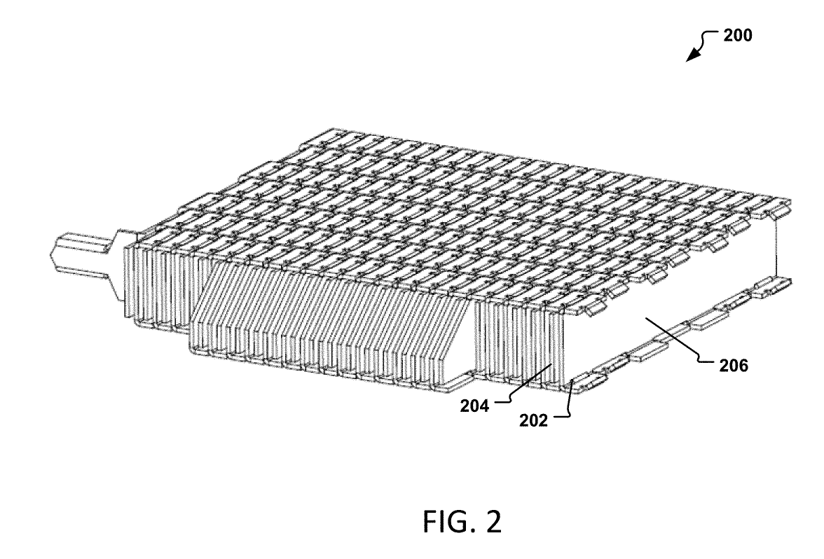

FIG. 2 illustrates a perspective view of an assembled plurality of fins 200. As described above, an arm 202 of a first fin structure 204 is angled and fits through a cutout portion of a second fin structure 206. The complementary parts interleave, and the interlocking of the paired parts allows for a small pitch. A pitch includes a dimension from the start of one fin to the start of another fin from an end on view perspective.

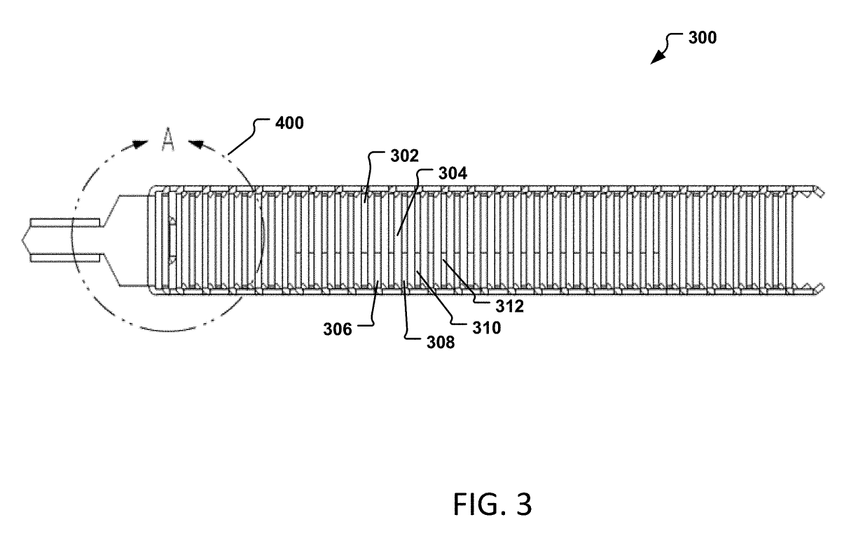

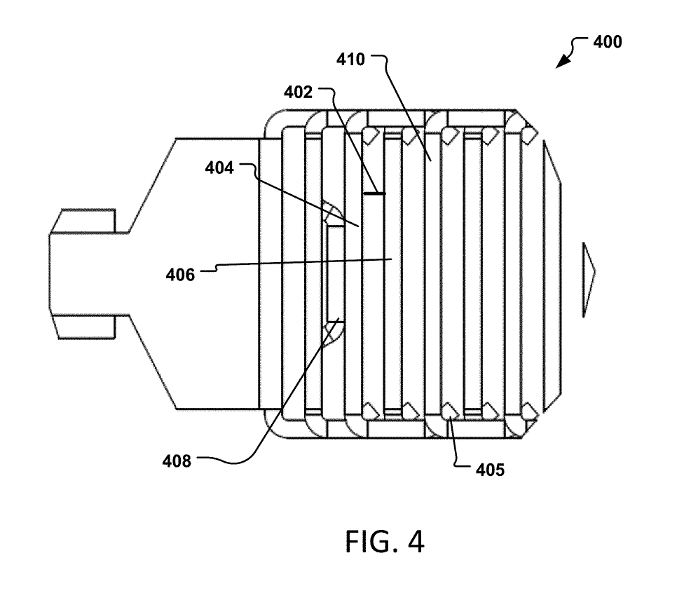

The pitch is more clearly shown in the side view of an assembled plurality of fins 300 of FIG. 3, as well as in the magnified portion 400 of the plurality of fins 300 shown in FIG. 4. As shown, a fin structure 302 attaches to a second fin structure 304. A third fin structure 306 attaches to a fourth fin structure 308. A fifth fin structure 310 attaches to sixth fin structure 312.

A pitch 402 is denoted between a fin structure 404 and another fin structure 406. An emboss 408 is shown positioned within the plurality of fins 400. As described herein, the emboss 408 may be positioned proximate each end of a plurality of attached fin structures may set a gap between fin sections throughout the plurality. For instance, one embodiment of the system may set that fin pitch at a half inch. Where desired, an emboss may be positioned within an interlocked fin structure further away from a heat source than other fin sections of the interlocked fin structure. An illustrative emboss may be stamped or punched into a fin structure. As shown in FIG. 4, an arm 405 of the fin structure 404 connects to another fin structure 410.

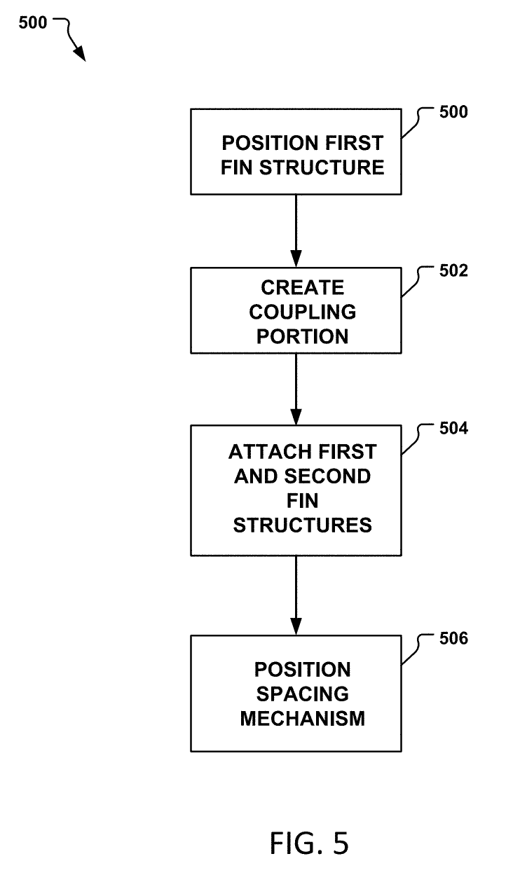

FIG. 5 is a flowchart of an embodiment of a method 500 of manufacturing a plurality of fin structures. The method includes at 502 positioning a first fin structure within the plurality of fin structures. A flat portion of the first fin structure may allow a cooling medium to travel across. The fin structure may be created to have a coupling portion having an aperture, and also having an arm,

At 504, the coupling portion may be attached to a corresponding aperture in a corresponding coupling portion of a corresponding second sink fin structure. The corresponding second sink fin structure may be more than one sink fin structure away from the first heat sink fin.

A spacing mechanism may be positioned at 506. As described herein, the spacing mechanism may maintain consistent fin section spacing.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

In the following, reference is made to embodiments presented in this disclosure. However, the scope of the present disclosure is not limited to specific described embodiments. Instead, any combination of the following features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the following aspects, features, embodiments and advantages are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

The flowchart and block diagrams in the Figures illustrate the architecture, functionality, and operation of possible implementations of systems and methods according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While the foregoing is directed to embodiments of the present invention, other and further embodiments of the invention may be devised without departing from the basic scope thereof, and the scope thereof is determined by the claims that follow.

What is claimed is:

1. An apparatus comprising:
a first fin structure;
a flat portion of the first fin structure for a cooling medium to travel across;
a coupling portion on a first edge of the flat portion, the coupling portion having an aperture, and also having an arm, the coupling portion long enough to attach to a corresponding aperture in a corresponding coupling portion of a corresponding second sink fin structure, the corresponding second sink fin structure being more than one fin structure away from the first heat sink fin.

2. The apparatus of claim 1, wherein the arm is angled with respect to a direction of flow of the cooling medium.

3. The apparatus of claim 1, wherein the arm reaches in a substantially orthogonal direction relative to the flow of the cooling medium.

4. The apparatus of claim 1, further comprising a third fin structure having a cutout to allow a leg of the first fin to extend to at least two times a fin pitch in a direction towards the second fin structure.

5. The apparatus of claim 1, further comprising a spacing mechanism to prevent relative motion between the first fin structure and a third fin structure, wherein the third fin structure is positioned in between the first and second fin structures.

6. The apparatus of claim 5, wherein the spacing mechanism is positioned away from a heat source within a group of a plurality of fin structures, wherein the plurality of fin structures includes the first and second fin structures.

7. The apparatus of claim 5, wherein the spacing mechanism is at least one of an emboss, a bridgelance, and a formed feature.

8. The apparatus of claim 5, wherein the spacing mechanism is used to set a pitch.

9. The apparatus of claim 1, wherein the corresponding second sink fin structure is more than two sink fin structures away from the first heat sink fin.

10. The apparatus of claim 1, wherein the corresponding second sink fin structure is more than three sink fin structures away from the first heat sink fin.

11. An apparatus comprising:
a first fin structure for a cooling medium to travel across, the first fin structure including a coupling portion;
a second fin structure configured to be attached to the first fin structure via the coupling portion; and
a third fin structure positioned between the first and second fin structures, wherein the coupling structure extends through the third fin structure.

12. The apparatus of claim 11, further comprising a spacing mechanism to prevent relative motion between the first fin structure and the third fin structure.

13. A method of manufacturing a plurality of fin structures, the method comprising:
positioning a first fin structure within the plurality of fin structures, wherein a flat portion of the first fin structure allows a cooling medium to travel across;
creating a coupling portion on a first edge of the flat portion, the coupling portion having an aperture, and also having an arm;
attaching the coupling portion to a corresponding aperture in a corresponding coupling portion of a corresponding second sink fin structure, wherein the corresponding second sink fin structure being more than one sink fin structure away from the first heat sink fin.

14. The method of claim 13, further comprising angling the arm with respect to a direction of the flow of the cooling medium.

15. The method of claim 13, further comprising angling the arm substantially orthogonally with respect to a direction of the flow of the cooling medium.

16. The method of claim 13, further comprising including a spacing mechanism to prevent relative motion between the first fin structure and the third fin structure.

17. The method of claim 16, wherein the spacing mechanism is at least one of an emboss, a bridgelance, and a formed feature.

18. The method of claim 13, further comprising setting a pitch of the plurality of fin structures.

19. The method of claim 18, further comprising using a spacing mechanism to set a pitch of the plurality of fin structures.

20. The method of claim 13, further comprising positioning at least two fin structures between the first and second fin structures.
